(19) United States
(12) Patent Application Publication
(10) Pub. No.: US 2023/0057157 A1
(43) Pub. Date: Feb. 23, 2023

(54) SEMICONDUCTOR DEVICE AND METHOD FOR OPERATING THE SAME

(71) Applicant: CHANGXIN MEMORY TECHNOLOGIES, INC., Hefei City, Anhui (CN)

(72) Inventor: Ping JIANG, Hefei City, Anhui (CN)

(21) Appl. No.: 17/599,718

(22) PCT Filed: May 21, 2021
(86) PCT No.: PCT/CN2021/095071

§ 371 Date: Sep. 29, 2021

(30) Foreign Application Priority Data
Jun. 5, 2020 (CN) 20201054657.7

(51) Int. Cl. G03F 7/30

(52) U.S. Cl. CPC G03F 7/30

(57) ABSTRACT

The present disclosure relates to a semiconductor device, including: at least two processing units; a processing liquid spraying arm, which is located above the processing units; a fixed baffle, located between the adjacent processing units, the fixed baffle being provided with an opening by which the adjacent processing units are communicated, the processing liquid spraying arm moving between the adjacent processing units through the opening; a movable baffle, located at least on one side of the fixed baffle or located in the fixed baffle; a first driving apparatus, connected to the movable baffle and configured to drive the movable baffle to move to completely block the opening when the processing liquid spraying arm stops in the processing unit, so as to isolate the adjacent processing units, and drive the movable baffle to move to unblock the opening when the processing liquid spraying arm moves between the adjacent processing units.

### CROSS-REFERENCE TO RELATED APPLICATIONS

The present disclosure claims the priority to Chinese Patent Application 202010504657.7, titled “SEMICONDUCTOR DEVICE AND METHOD FOR OPERATING THE SAME”, filed on Jun. 5, 2020, which is incorporated herein by reference in its entirety.

### TECHNICAL FIELD

The present disclosure relates to the field of semiconductor devices, and in particular to a semiconductor device and a method for operating the same.

### BACKGROUND

In the existing developing devices, the space for the developing units is limited. A developing liquid spraying arm is generally used to simultaneously develop wafers in two developing units. However, although this method saves space, there will be interferences between the two developing units in actual operation. On one hand, the adjacent developing units may splash the developing liquid during the operation, which will cause defects. On the other hand, the developing liquid spraying arm may disrupt the balance of the wind speed and the flow direction in the developing units during its movement and operation, resulting in low uniformity of the wafer surface, which in turn affects the critical dimension (CD) of the development.

### SUMMARY

One aspect of the present disclosure provides a semiconductor device, comprising:

at least two processing units, each of the processing units is provided with a carrier for placing a wafer to be processed;

a processing liquid spraying arm, the processing liquid spraying arm is located above the processing units and is able to move between the adjacent processing units to spray processing liquid on a surface of the wafer to be processed in each of the processing units;

a fixed baffle, located between the adjacent processing units, the fixed baffle being provided with an opening, by the opening the adjacent processing units are communicated, the processing liquid spraying arm moving between the adjacent processing units through the opening;

a movable baffle, located at least on one side of the fixed baffle;

a first driving apparatus, connected to the movable baffle and configured to drive the movable baffle to move to completely block the opening when the processing liquid spraying arm stops in the processing unit, so as to isolate the adjacent processing units, and drive the movable baffle to move to unblock the opening when the processing liquid spraying arm moves between the adjacent processing units.

Another aspect of the present disclosure further provides a method for operating the semiconductor device as described above, comprising:

driving the movable baffle to move to unblock the opening when the processing liquid spraying arm moves from one processing unit to another adjacent processing unit where the wafer to be processed is placed; and driving the movable baffle to move to completely block the opening after the processing liquid spraying arm moves to the processing unit where the wafer to be processed is placed.

The details of one or more embodiments of the present disclosure will be set forth in the following drawings and description. Other features, objects and advantages of the present disclosure will become apparent from the description, drawings and claims.

### BRIEF DESCRIPTION OF THE DRAWINGS

In order to more clearly describe the technical solutions of the embodiments of the present disclosure, reference may be made to one or more drawings. However, the additional details or examples used to describe the drawings should not be considered as any limitations to any of inventions of the present disclosure and embodiments or preferred implementations currently described.

FIG. 1 is a schematic partial structure diagram of a semiconductor device in an embodiment of the present disclosure, when viewed from the top;

FIG. 2 is a schematic view of the semiconductor device in an embodiment of the present disclosure, when the opening is completely blocked by the movable baffle;

FIG. 3 is a schematic view of the semiconductor device in an embodiment of the present disclosure, when the movable baffle moves to unblock the opening as the processing liquid spraying arm moves from one processing unit to another processing unit;

FIG. 4 is a schematic view of the semiconductor device in an embodiment of the present disclosure, when the processing liquid spraying arm operates in a processing unit and moves between adjacent processing units; and

FIG. 5 is a flowchart of a method for operating the semiconductor device in another embodiment of the present disclosure.

### DETAILED DESCRIPTION

In order to facilitate the understanding of the present disclosure, the present disclosure will be described more fully below with reference to the relevant drawings. Preferred embodiments of the present disclosure are shown in the drawings. However, the present disclosure may be implemented in many different forms and is not limited to the embodiments described herein. On the contrary, these embodiments are provided to make the disclosure of the present disclosure more thorough and comprehensive.

Unless otherwise defined, all technical and scientific terms used herein have the same meaning as commonly understood by a person of ordinary skill in the art to which the present disclosure belongs.

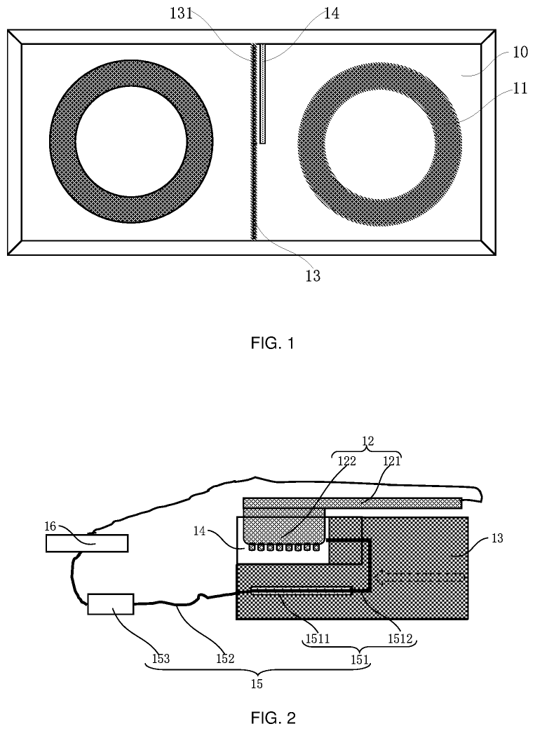

As shown in FIGS. 1-4, the present disclosure provides a semiconductor device, comprising: at least two processing units 10, each of which is provided with a carrier 11 for placing a wafer 17 to be processed; a processing liquid spraying arm 12, which is located above the processing units 10 and is able to move between the adjacent processing units 10 to spray processing liquid on the surface of the wafer 17 to be processed in each of the processing units 10; a fixed baffle 13 located between the adjacent processing units 10, the fixed baffle 13 being provided with an opening 131 by which the adjacent processing units 10 are communicated, the processing liquid spraying arm 12 moving between the adjacent processing units 10 through the opening 131; a movable baffle 14 located at least on one side of the fixed baffle 13 or located in the fixed baffle 13; a first driving apparatus 15, connected to the movable baffle 14 and configured to drive the movable baffle 14 to move to completely block the opening 131 when the processing liquid spraying arm 12 stops in the processing unit 10, so as to isolate the adjacent processing units 10, and drive the movable baffle 14 to move to unblock the opening 131 when the processing liquid spraying arm 12 moves between the adjacent processing units 10.

In an example, the semiconductor device further comprises an equipment chamber, the processing unit 10, the processing liquid spraying arm 12, the fixed baffle 13 and the movable baffle 14 are all located in the equipment chamber, and the fixed baffle 13 and the equipment chamber are fixedly connected by a fixed screw. In this way, the fixed baffle 13 can be simply and stably mounted in the equipment chamber. Additional modification of the equipment chamber is avoided.

The semiconductor device in the present disclosure is provided with the fixed baffle 13 and the movable baffle 14 between adjacent processing units 10. The independence of the operations of the two processing units 10 can be ensured without changing the interior of the semiconductor device, thereby reducing the probability of defects and ensuring the uniformity of the critical dimension of the development.

In an example, the processing liquid spraying arm 12 may comprise: an arm body 121 and a sprayer 122; the arm body 121 is provided with a processing liquid delivery pipeline (not shown); and the sprayer 122 is located at one end of the arm body 121 and is communicated with the processing liquid delivery pipeline. Of course, in other examples, the processing liquid delivery pipeline may be located on the surface of the arm body 121. Specifically, there may be one or more sprayers 122. When there are multiple sprayers 122, the specific number of sprayers may be set according to actual needs. It is not limited in the present disclosure.

In an optional embodiment, the size and shape of the opening 131 are adapted to the size and shape of the sprayer 122, to allow the sprayer 122 to enter and exit the opening 131, so as to minimize the area of the opening 131.

In an example, the bottom of the fixed baffle 13 and the bottom of the chamber are hermetically combined, and a second opening is formed between the top of the fixed baffle 13 and the top of the equipment chamber. The processing liquid spraying arm 12 moves between adjacent processing units 10. Specifically, the sprayer 122 can move freely from the first opening, and the arm body 121 can move freely in the second opening, so that the processing liquid spraying arm 12 will not be hindered during the movement. In addition, the size of the second opening may be set according to the size of the arm body 121 to ensure that the processing liquid will not splash into the adjacent processing unit 10 from the second opening.

In an example, the semiconductor device may be a developing device, the processing unit 10 comprises a developing unit; the processing liquid spraying arm 12 is a developing liquid spraying arm; and the processing liquid is developing liquid. Of course, in other examples, the semiconductor device may be other process devices such as a wet etching device. In this case, the processing unit 10 may be a wet etching unit, the processing liquid spraying arm 12 may be a wet etching liquid spraying arm, and the processing liquid may be wet etching liquid.

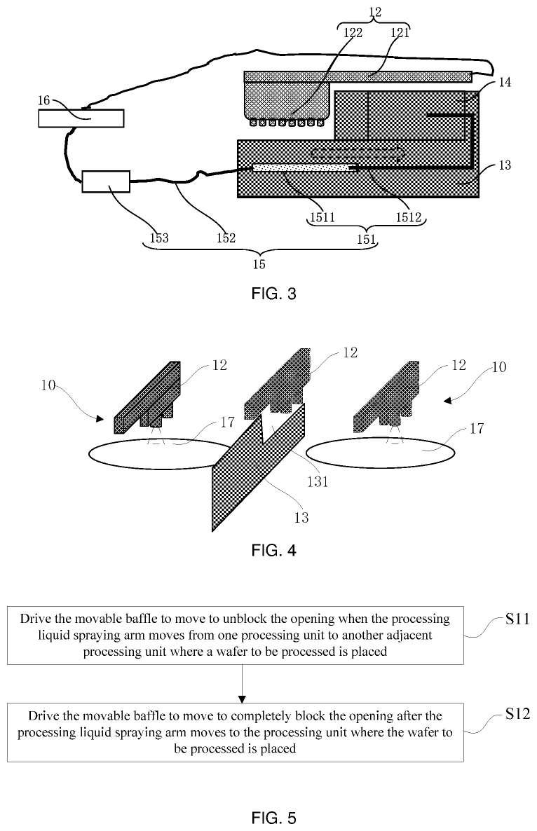

In an example, the first driving apparatus 15 comprises: a cylinder 151 comprising a cylinder body 1511 and a driving rod 1512, the cylinder body 1511 being provided with an accommodating cavity (not shown), one end of the driving rod 1512 being located in the accommodating cavity and the other end of the driving rod being fixedly connected to the movable baffle 14; a gas pipeline 152, one end of which is connected to the accommodating cavity and the other end of which is connected to a gas source (not shown); and a solenoid valve 153, located on the gas pipeline 152 and configured to control the on-off of the gas pipeline 152. The working principle of the first driving apparatus 15 will be described below. When it is necessary to push the driving rod 1512 to move outward, the solenoid valve 153 may be opened. At this time, the gas pipeline 152 supplies gas to the accommodating cavity to push the driving rod 1512 to move outward. Then, the movable baffle 14 may be driven to move to the right, as shown in FIG. 3. When the driving rod 1512 needs to be returned to the initial position, the solenoid valve 153 may be closed, and no gas is supplied to the accommodating cavity. In this way, the driving rod 1512 moves back to the initial position (specifically, the movement of the driving rod 1512 back to the initial position may be realized by a spring). Of course, in other examples, the first driving apparatus 15 may be any other driving apparatus that can drive the movable baffle 14 to move. It is not limited in the present disclosure.

In an example, the cylinder 151 may be fixed on the fixed baffle 13. The first driving apparatus 15 may further comprise a cylinder fixing bracket (not shown). The movable baffle 14 may be arranged on the cylinder fixing bracket. Of course, in other examples, the cylinder 151 may be fixed at any position in the processing unit 10 under the premise of ensuring that its function can be performed normally without affecting the normal operation of the semiconductor device. The movable baffle 14 may be arranged at any position in the processing unit 10 on a side of the fixed baffle 13 under the premise of ensuring that its function can be performed normally without affecting the normal operation of the semiconductor device.

In an example, the semiconductor device further comprises a second driving apparatus (not shown). The second driving apparatus is connected to the processing liquid spraying arm 12 and configured to drive the processing liquid spraying arm 12 to move. Specifically, the second driving apparatus drives the processing liquid spraying arm 12 to move between the adjacent processing units 10 when the processing liquid spraying arm 12 needs to move between the adjacent processing units 10. The structure of the second driving apparatus may be the same as the structure of the first driving apparatus.

In an example, the semiconductor device further comprises a control apparatus 16 connected to the processing liquid spraying arm 12 and the movable baffle 14 and configured to control the first driving apparatus 15 to drive the movable baffle 14 to move so as to unblock the opening 131 when controlling the second driving apparatus to drive the processing liquid spraying arm 12 to move between the adjacent processing units 10, and control the first driving apparatus 15 to drive the movable baffle 14 to move to completely block the opening 131 after the processing liquid spraying arm 12 moves to the target processing unit 10.

Specifically, the control apparatus 16 may comprise a programmable logic controller (PLC). The specific structure of the programmable logic controller that can implement the above-mentioned signal distribution function is known to those skilled in the art, and will not be repeated here.

In an example, the fixed baffle 13 and the movable baffle 14 are both metal baffles, such as stainless steel baffles. Specifically, the material for the fixed baffle 13 and the movable baffle 14 may be the same as the material for the semiconductor device housing. Of course, in other examples, the material for the fixed baffle 13 and the movable baffle 14 may be other materials. It is not limited in the present disclosure.

In an example, the movable baffle 14 is located at least on one side of the fixed baffle 13. Specifically, the movable baffle 14 may be located on one side of the fixed baffle 13, as shown in FIG. 1. In this case, there is a distance between the movable baffle 14 and the fixed baffle 13. By setting a distance between the movable baffle 14 and the fixed baffle 13, it can be ensured that the movable baffle 14 is not in direct contact with the fixed baffle 13. When the movable baffle 14 moves, it will not rub against the fixed baffle 13 to generate particles. Contamination to the processing units 10 and the wafers in the processing units 10 is avoided. The generation of particle defects is avoided.

Specifically, the distance between the movable baffle 14 and the fixed baffle 13 may be set according to actual needs. In this embodiment, the distance between the movable baffle 14 and the fixed baffle 13 may be 0.5 mm to 2 mm. More specifically, the distance between the movable baffle 14 and the fixed baffle 13 may be 0.5 mm, 1 mm, 1.5 mm, 2 mm, etc.

The working principle of the semiconductor device according to the present disclosure is as follows. First, the processing liquid spraying arm 12 is located in a processing unit 10 where a wafer 17 to be processed is placed, and the processing liquid spraying arm 12 is used to spray the processing liquid on the surface of the wafer 17 to be processed below it. At this time, the movable baffle 14 completely blocks the opening 131 to isolate the adjacent processing units 10, as shown in FIGS. 1 and 2. After spraying, the control apparatus 16 controls the second driving apparatus to drive the processing liquid spraying arm 12 to move from one processing unit 10 to another adjacent processing unit 10 where the wafer 17 to be processed is placed, and the control apparatus 16 controls the first driving apparatus 15 to drive the movable baffle 14 to move to unblock the opening 131 as the processing liquid spraying arm 12 moves, as shown in FIG. 3. After the processing liquid spraying arm 12 moves to the processing unit 10 where the wafer 17 to be processed is placed, the control apparatus 16 controls the first driving apparatus 15 to drive the movable baffle 14 to move to completely block the opening 131, so as to isolate two adjacent processing units 10. The processing liquid spraying arm 12 sprays the processing liquid on the surface of the wafer 17 to be processed below it. After spraying, the step of moving the processing liquid spraying arm 12 is repeated to realize the movement of the processing liquid spraying arm 12 between adjacent processing units 10 and the spraying of the developing liquid on the surface of the wafer 17 to be processed in each of the processing units 10.

As shown in FIG. 5, the present disclosure further provides a method for operating a semiconductor device. The operating method is performed based on the semiconductor device according to any one of the embodiments shown in FIGS. 1-4 in the above embodiment. For the specific structure of the semiconductor device, please refer to FIGS. 1-4 and the description of the above embodiment, which will not be repeated here. The operating method may comprise:

S11: driving the movable baffle 14 to move to unblock the opening 131 when the processing liquid spraying arm 12 moves from one processing unit 10 to another adjacent processing unit 10 where a wafer 17 to be processed is placed; and

S12: driving the movable baffle 14 to move to completely block the opening 131 after the processing liquid spraying arm 12 moves to the processing unit 10 where the wafer 17 to be processed is placed.

Specifically, in the step S11, the control apparatus 16 controls the second driving apparatus to drive the processing liquid spraying arm 12 to move from one processing unit 10 to another adjacent processing unit 10 where the wafer 17 to be processed is placed, and the control apparatus 16 controls the first driving apparatus 15 to drive the movable baffle 14 to move to unblock the opening 131 as the processing liquid spraying arm 12 moves.

Specifically, in the step S12, after the processing liquid spraying arm 12 moves to the processing unit 10 where the wafer 17 to be processed is placed, the control apparatus 16 controls the first driving apparatus 15 to drive the movable baffle 14 to move to completely block the opening 131, so as to isolate two adjacent processing units 10.

In an example, before the step S11, it further comprises a step of spraying, by the processing liquid spraying arm 12, the processing liquid on the surface of the wafer 17 to be processed below the processing liquid spraying arm 12. Specifically, the processing liquid spraying arm 12 is located in the processing unit 10 where the wafer 17 to be processed is placed. The processing liquid spraying arm 12 is used to spray the processing liquid on the surface of the wafer 17 to be processed below it. At this time, the movable baffle 14 completely blocks the opening 131 to isolate the adjacent processing units 10.

In an example, after the step S12, the method further comprises a step of spraying, by the processing liquid spraying arm 12, the processing liquid on the surface of the wafer 17 to be processed below the processing liquid spraying arm 12.

In an example, after driving the movable baffle 14 to move to completely block the opening 131 and after spraying, by the processing liquid spraying arm 12, the processing liquid on the surface of the wafer 17 to be processed below the processing liquid spraying arm 12, the method further comprises a step of repeating the above steps at least one time, in order to realize the movement of the processing liquid spraying arm 12 between the adjacent processing units 10 and the spraying of the developing liquid on the surface of the wafer 17 to be processed in each of the processing units 10.

Various technical features of the above embodiments can be arbitrarily combined. For simplicity, not all possible combinations of various technical features of the above embodiments are described. However, all those technical features shall be included in the protection scope of the present disclosure if not conflict.

The embodiments described above are merely some implementations of the present disclosure. Although those embodiments have been described in specific details, they are not construed as any limitation to the scope of the present disclosure. It should be noted that, for a person of ordinary skill in the art, a number of variations and improvements may be made without departing from the concept of the present disclosure, and those variations and improvements should be regarded as falling into the protection scope of the present disclosure. Therefore, the protection scope of the present disclosure should be subject to the appended claims.

1. A semiconductor device, comprising:
at least two processing units, each of the processing units is provided with a carrier for placing a wafer to be processed;
a processing liquid spraying arm, the processing liquid spraying arm is located above the processing units and is able to move between the adjacent processing units to spray processing liquid on a surface of the wafer to be processed in each of the processing units;
a fixed baffle, located between the adjacent processing units, the fixed baffle being provided with an opening, by the opening the adjacent processing units are communicated, the processing liquid spraying arm moving between the adjacent processing units through the opening;
a movable baffle, located at least on one side of the fixed baffle;
a first driving apparatus, connected to the movable baffle and configured to drive the movable baffle to move to completely block the opening when the processing liquid spraying arm stops in the processing unit, so as to isolate the adjacent processing units, and drive the movable baffle to move to unblock the opening when the processing liquid spraying arm moves between the adjacent processing units.

2. The semiconductor device according to claim 1, wherein the first driving apparatus comprises:
a cylinder, comprising a cylinder body and a driving rod, the cylinder body being provided with an accommodating cavity, one end of the driving rod being located in the accommodating cavity and the other end of the driving rod being connected to the movable baffle;
a gas pipeline, one end of the gas pipeline is connected to the accommodating cavity and the other end of the gas pipeline is connected to a gas source; and
a solenoid valve, located on the gas pipeline and configured to control an on-off of the gas pipeline.

3. The semiconductor device according to claim 1, wherein the semiconductor device further comprises a second driving apparatus, connected to the processing liquid spraying arm and configured to drive the processing liquid spraying arm to move.

4. The semiconductor device according to claim 3, wherein the semiconductor device further comprises a control apparatus, connected to the processing liquid spraying arm and the movable baffle and configured to control the first driving apparatus to drive the movable baffle to move so as to unblock the opening when controlling the second driving apparatus to drive the processing liquid spraying arm to move between the adjacent processing units, and control the first driving apparatus to drive the movable baffle to move to completely block the opening after the processing liquid spraying arm moves to a target processing unit.

5. The semiconductor device according to claim 1, wherein the fixed baffle and the movable baffle are both metal baffles.

6. The semiconductor device according to claim 1, wherein, when the movable baffle is located at least on one side of the fixed baffle, there is a distance between the movable baffle and the fixed baffle.

7. The semiconductor device according to claim 6, wherein the distance between the movable baffle and the fixed baffle is 0.5 mm to 2 mm.

8. The semiconductor device according to claim 1, wherein the semiconductor device further comprises an equipment chamber, the processing unit, the processing liquid spraying arm, the fixed baffle and the movable baffle are all located in the equipment chamber, and the fixed baffle and the equipment chamber are fixedly connected by a fixed screw.

9. A method for operating the semiconductor device according to claim 1, comprising:
driving the movable baffle to move to unblock the opening when the processing liquid spraying arm moves from one processing unit to another adjacent processing unit where the wafer to be processed is placed; and
driving the movable baffle to move to completely block the opening after the processing liquid spraying arm moves to the processing unit where the wafer to be processed is placed.

10. The operating method according to claim 9, before the processing liquid spraying arm moves from one processing unit to another adjacent processing unit where the wafer to be processed is placed, the operating method further comprises spraying, by the processing liquid spraying arm, the processing liquid on the surface of the wafer to be processed below the processing liquid spraying arm;
after driving the movable baffle to move to completely block the opening, the operating method further comprises spraying, by the processing liquid spraying arm, the processing liquid on the surface of the wafer to be processed below the processing liquid spraying arm; and
after driving the movable baffle to move to completely block the opening and after spraying, by the processing liquid spraying arm, the processing liquid on the surface of the wafer to be processed below the processing liquid spraying arm, the operating method further comprises repeating the above steps at least one time.
